(19) United States
(12) Patent Application Publication
(10) Pub. No.: US 2026/0165196 A1
(43) Pub. Date: Jun. 11, 2026

(54) SEMICONDUCTOR DEVICE AND METHODS OF FORMATION

(71) Applicant: Taiwan Semiconductor Manufacturing Company, Ltd., Hsinchu (TW)

(72) Inventor: Kuei-Sung CHANG, Kaohsiung City (TW)

(21) Appl. No.: 19/058,480

(22) Filed: Feb. 20, 2025

Related U.S. Application Data
(60) Provisional application No. 63/728,989, filed on Dec. 6, 2024.

(51) Int. Cl. H01L 23/10; H01L 21/308; H01L 23/00; H01L 23/538; H01L 25/00; H01L 25/065

(52) U.S. Cl. CPC H10W 76/60; H10P 50/692; H10W 70/611; H10W 70/685; H10W 90/00; H10W 72/0198; H10W 72/07236; H10W 72/07255; H10W 72/2524; H10W 80/327; H10W 90/724; H10W 90/792

(57) ABSTRACT

Product dies that include micro-electromechanical-system (MEMS) devices are manufactured on a wafer along with one or more process control monitoring (PCM) dies. The width of a seal structure around a cavity in the one or more PCM dies on the wafer is controlled so that the cavities of the PCM dies are more susceptible to gas leakage than the cavities of the product dies. The width of the seal structure enables measurement of a change in the cavity pressure of a PCM die to be performed between a first time T₀ and a second time T₁. The change in cavity pressure may cause the quality factor (Q) of the PCM die to change by a greater amount than the product dies, thereby enabling leakage to be more easily detectable in the PCM dies without subjecting the product dies to damaging levels of stress. The seal structure may have various designs.

### CROSS-REFERENCE TO RELATED APPLICATION

This Patent Application claims priority to Provisional Patent Application No. 63/728,989, filed on Dec. 6, 2024, and entitled “SEMICONDUCTOR DEVICE AND METHODS OF FORMATION.” The disclosure of the prior Application is considered part of and is incorporated by reference into this Patent Application.

### BACKGROUND

Integrated circuits may be fabricated on a semiconductor wafer. Semiconductor wafers can be stacked or bonded on top of each other to form what is referred to as a three-dimensional integrated circuit. Some semiconductor wafers include micro-electromechanical-system (MEMS) devices, which involve the process of forming micro-structures with dimensions on the micrometer scale (one millionth of a meter). MEMS devices may be built on silicon wafers and realized in thin films of materials. MEMS applications include inertial sensor applications, such as motion sensors, accelerometers, and gyroscopes. Other MEMS applications include optical applications, such as movable mirrors, and radio frequency (RF) applications, such as RF switches and resonators.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example semiconductor device described herein.

FIGS. 2A-2G are diagrams of example implementations of bonding structures described herein.

FIGS. 3A-3D are diagrams of example implementations of cavity structures described herein.

FIGS. 4A-4C are diagrams of example semiconductor devices described herein.

FIG. 5 is a diagram of an example implementation of a semiconductor structure described herein.

FIGS. 6A-6F are diagrams of an example implementation of forming a first wafer of a semiconductor device described herein.

FIGS. 7A-7C are diagrams of an example implementation of forming a second wafer of a semiconductor device described herein.

FIGS. 8A and 8B are diagrams of an example implementation of bonding and dicing wafers of a semiconductor device described herein.

FIG. 9 is a graph of quality factor as a function of pressure change described herein.

FIG. 10 is a graph of quality factor differences described herein.

FIG. 11 is a flowchart of an example process associated with forming a semiconductor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A MEMS device may include multiple devices or wafers that are bonded together to form the MEMS device. For example, a MEMS device may include a circuitry wafer (e.g., a complementary metal oxide semiconductor (CMOS) wafer) that includes circuitry for the MEMS device, a device wafer that includes suspended mechanical components that function as actuators of the MEMS device, and a cavity (or capping) wafer to seal the mechanical components in a cavity or micro-chamber. The circuitry wafer, the device wafer, and/or the capping wafer may be bonded together using a eutectic bonding process and/or a fusion bonding process. Eutectic bonding is a wafer bonding technique by which the wafers of the MEMS device are heated to form a eutectic system between the materials of the wafers. The eutectic system typically includes silicon or germanium and a metal such as gold or aluminum. Because a eutectic system is formed, both materials will diffuse into each other and form bonding at a eutectic point. Fusion bonding is a wafer bonding technique of bonding silicon (Si) to silicon (Si), silicon (Si) to a silicon oxide (e.g., SiOₓ, such as SiO₂), or a silicon oxide to a silicon oxide (e.g., SiO₂ to SiO₂).

Devices such as, for example, a MEMS resonator, a MEMS accelerometer, a MEMS gyroscope, etc., may operate optimally in a vacuum environment. In the vacuum environment, a device may be hermetically sealed within a cavity (e.g., micro-chamber) under vacuum conditions. A hermetic seal might fail due to, for example, process abnormalities and/or defects. Hermeticity detection can be used to test hermetic seals to ensure that the hermetic seals are intact. Hermeticity detection may rely on detection of pressure changes within the cavity. A pressure sensitive device (e.g., resonator, Pirani gauge) in the cavity may be used as a sensor to detect pressure changes.

A change in cavity pressure may negatively affect the performance of a MEMS device. For example, a quality factor (Q) of the MEMS device (e.g., a resonator) may be dependent on a vacuum pressure in the cavity of the MEMS device. The quality factor of a resonator corresponds to a ratio of the initial energy stored in the resonator to the energy lost in an oscillation cycle of the resonator. As the vacuum pressure (e.g., negative pressure) degrades (e.g., equalizes to the ambient pressure outside the cavity), the damping of the resonator is increased, thereby resulting in greater energy loss (and therefore, reduced quality factor) per oscillation of the resonator.

Pressure inside a cavity can vary depending on different factors such as, for example, outgassing and/or gas leakage. “Outgassing” refers to the flow of gas out of a cavity that may have been trapped in the cavity during a fabrication process (e.g., a deposition process). “Gas leakage” refers to the flow of gas from outside of a cavity into the cavity (e.g., because of the negative pressure, or vacuum, in the cavity). A width of a seal structure (e.g., seal ring) around the cavity may be sufficiently large so that the time for gas to diffuse into the cavity will be long enough to allow for unimpeded operation of a MEMS device. However, if a gas leakage path occurs through the seal structure, the leakage amount may be too small to detect over a given period of time because of the width of the seal structure. For example, since diffusion of gas occurs over time, after a certain time, leakage starts to change the pressure in the cavity, which changes the quality factor of the MEMS device. However, because the amount of leakage over time is small, the change in the quality factor over time may not be sufficiently large to detect the leakage because the amount that damping on the MEMS device increases over time may be small. As a result of the leakage being undetected, the leakage may degrade the quality of the vacuum in the cavity, thereby reducing the sensitivity of the MEMS device, decreasing the accuracy of the MEMS device, and/or causing the MEMS device to fail.

In some cases, the MEMS device may be subjected to increased stress conditions to induce a greater amount of gas leakage so that process defects can be detected. However, over-stressing of the MEMS device can alter the operation of the MEMS device and/or can degrade the performance of the MEMS device.

In some implementations described herein, product dies that include MEMS devices are manufactured on a wafer along with one or more process control monitoring (PCM) dies. The width of a seal structure around a cavity in the one or more PCM dies on the wafer is controlled so that the cavities of the PCM dies are more susceptible to gas leakage than the cavities of the product dies. The greater susceptibility to gas leakage allows for a greater amount of gas leakage into the cavity to be detected in the PCM dies during testing when process variations or defects occur on the wafer. In more detail, the width of the seal structure enables measurement of a change in the cavity pressure of a PCM die to be performed between a first time T₀ and a second time T₁. The change in cavity pressure may cause the quality factor (Q) of the PCM die to change by a greater amount than the product dies, thereby enabling leakage to be more easily detectable in the PCM dies without subjecting the product dies to damaging levels of stress. The seal structure may have different design variations for the shape of the seal structure, and for the locations at which the width is controlled. The quantity of PCM dies and product dies on a wafer can also vary.

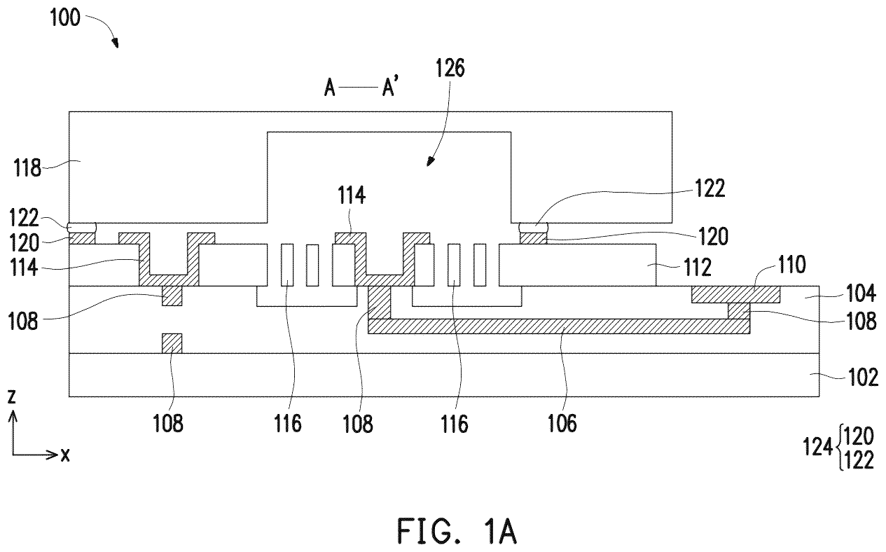

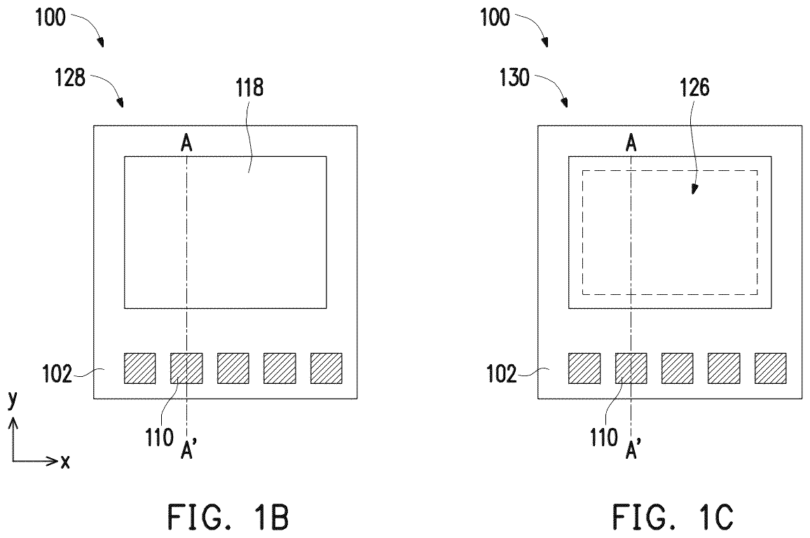

FIGS. 1A-1C are diagrams of an example semiconductor device 100 described herein. The semiconductor device 100 may be a MEMS device, such as a MEMS resonator, a MEMS accelerometer, a MEMS gyroscope, etc., among other examples. As shown in FIG. 1, the semiconductor device 100 may include a device wafer 102. The device wafer 102 may be a complementary metal oxide semiconductor (CMOS) wafer that includes semiconductor components such as transistors, inductors, capacitors, and/or resistors; that includes integrated circuits; and/or that includes interconnecting metallization layers of the semiconductor device 100. The device wafer may include a substrate of the semiconductor device 100. The substrate may correspond to a portion of a device wafer 102, and may include a silicon (Si) substrate, a substrate formed of a material including silicon, a III-V compound semiconductor material substrate such as gallium arsenide (GaAs), a silicon on insulator (SOI) substrate, or another type of substrate.

An interconnect layer 104 is formed on the device wafer 102 in a z-direction in the semiconductor device 100. The interconnect layer 104 may include one or more dielectric layers such as, for example, a silicon nitride (SiₓN_{y}), an oxide (e.g., a silicon oxide (SiOₓ) and/or another oxide material), and/or another type of dielectric material. The interconnect layer 104 may also include one or more interlayer dielectric (ILD) layers, one or more etch stop layer (ESLs), and/or another type of dielectric layer.

The ILD layers may each include a low dielectric constant (low-k) oxide material such as silicon oxide (SiOₓ) or undoped silicate glass (USG). Additionally and/or alternatively, the ILD layers may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs may each include a silicon nitride (SiₓN_{y}), silicon carbide (SiC), silicon oxynitride (SiON), and/or another suitable dielectric material. In some implementations, an ILD layer and an ESL include different dielectric materials to provide etch selectivity to enable various structures to be formed in the interconnect layer 104. For example, the ILD layers may each include a low-k dielectric material such as USG, and the ESLs may each include a high-k dielectric material such as silicon nitride (SiₓN_{y}) or silicon carbide (SiC). Additionally and/or alternatively, two or more ESLs may include different materials. For example, one or more first ESLs may include silicon nitride (SiₓN_{y}), and one or more second ESLs may include silicon carbide (SiC).

The interconnect layer 104 includes a plurality of conductive structures that are arranged in a plurality of layers. The conductive structures may be electrically coupled and/or physically coupled with one or more of integrated circuit devices and/or one or more MEMs devices. The conductive structures provide electrical routing that enables signals and/or power to be provided to and/or from the integrated circuit devices and/or MEMs devices.

The interconnect layer 104 may include metallization structures 106 and interconnect structures 108. The metallization structures 106 may include a combination of trenches, metallization layers, conductive traces, and/or other types of conductive structures. The interconnect structures 108 may include a combination of vias, interconnects, and/or other types of conductive structures. The metallization structures 106 and the interconnect structures 108 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 104 and the metallization structures 106, and/or between the dielectric layers of the interconnect layer 104 the interconnect structures 108. The one or more liner layers may include barrier liners, adhesion liners, and/or another type of liners. Examples of materials for the one or more liners include tantalum nitride (TaN) and/or titanium nitride (TiN), among other examples.

The interconnect layer 104 may further include one or more test pads 110 that may be used in connection with integrated circuit device and/or MEMs device testing (e.g., circuit probe (CP) testing and/or a wafer acceptance testing (WAT)). The test pads 110 may include a conductive material such aluminum (Al), copper, (Cu) aluminum copper (AlCu), tungsten (W), cobalt (Co), ruthenium (Ru), titanium (Ti), gold (Au) or another suitable conductive material. In some implementations, a periphery region (including the test pads 110) is included in a scribe area of the device wafer 102. In such a case, the periphery region may be excised (e.g., diced, sawn) from a semiconductor die prior to incorporating the semiconductor die in a semiconductor die package.

In some implementations, a semiconductor layer 112 is added to the device wafer 102 by fusion bonding a semiconductor substrate to a top surface of the interconnect layer 104. The semiconductor substrate may include a silicon (Si) substrate, a substrate formed of a material including silicon, a III-V compound semiconductor material substrate such as gallium arsenide (GaAs), or another type of substrate.

One or more contact structures 114 (e.g., through silicon vias (TSVs)) are formed through the semiconductor layer 112 to contact one or more interconnect structures 108 of the interconnect layer 104. The contact structures 114 may include a conductive material such aluminum (Al), copper, (Cu) aluminum copper (AlCu), tungsten (W), cobalt (Co), ruthenium (Ru), titanium (Ti), gold (Au) or another suitable conductive material. The contact structures 114 may be used to provide electrical routing that enables signals and/or power to be provided to and/or from the integrated circuit devices and/or MEMs devices. For example, one or more MEMS structures 116 (e.g., moveable MEMS structures) may be formed in the semiconductor layer 112, which may function as MEMS actuators for the semiconductor device 100 (e.g., MEMS device). The MEMS structure(s) 116 may be formed by etching through portions of the semiconductor layer 112 to form elongated members that are suspended above the interconnect layer 104 by a lateral connection to a side of the semiconductor layer 112 of the device wafer 102. In this way, the MEMS structure(s) 116 are permitted to move or displace to function as vibrating masses, elastic strings or coils, parallel plates for capacitive sensing, or other types of actuators for performing functions in resonators, sensors, gyroscopes, accelerometers, and/or other types of MEMS devices.

As shown in FIG. 1A, a capping wafer 118 is bonded with the device wafer 102 through the semiconductor layer 112. The capping wafer 118 is bonded to the semiconductor layer 112 by a bonding structure 124 (e.g., seal structure) including a stacked arrangement of a first bonding layer 120 and a second bonding layer 122. In some implementations, the first bonding layer 120 includes a metal, such as aluminum or gold, and the second bonding layer 122 includes a semiconductor material, such as germanium or silicon. The capping wafer 118 may include a substrate formed from a silicon wafer or another type of wafer that is used in semiconductor processing, that is capable of being etched, and has mechanical strength and material composition to form a cavity 126 in the capping wafer 118.

In some implementations, eutectic bonding is used to bond the capping wafer 118 to the semiconductor layer 112. In this case, the first and second bonding layers 120 and 122 diffuse into each other and bond at a eutectic point. Because a eutectic system is formed, there may be no discernible interface between the bonded first and second bonding layers 120 and 122. The eutectic bonding structure 124 may form a hermetic seal between the capping wafer 118 and the semiconductor layer 112 of the device wafer 102. The eutectic bonds between the semiconductor layer 112 and the capping wafer 118, and the fusion bond between the interconnect layer 104 and the semiconductor layer 112 form the cavity 126 in which the one or more MEMS structures 116 are hermitically sealed. The cavity 126 permits the MEMS structure(s) 116 to freely move or actuate, and prevents foreign objects and other contamination from damaging the MEMS structure(s) 116. The cavity 126 may be a hermetically sealed micro-chamber in which a vacuum is formed to prevent outgassing from, and gas leakage into, the cavity 126. The cavity 126 may be formed from the combination of the device wafer 102 and the capping wafer 118, which may enclose the MEMS structure(s) 116 in the cavity 126.

As explained in more detail herein, the bonding structure 124 is formed around the cavity 126 to surround the cavity 126 and to function as a seal structure to hermetically seal the cavity 126 between the capping wafer 118 and the semiconductor layer 112.

The number and arrangement of structures, layers, and/or the like shown in FIG. 1A are provided as an example. In practice, a MEMS structure may include additional structures and/or layers, fewer structures and/or layers, different structures and/or layers, or differently arranged structures and/or layers than those shown in FIG. 1A.

In addition, although FIG. 1A shows one semiconductor device 100, multiple semiconductor devices 100 including respective cavities 126 and their corresponding bonding structures 124 may be formed on the device wafer 102. For example, the device wafer 102 may include respective MEMs structures 116 formed in different portions of the semiconductor layer 112 and may be bonded to different portions of the capping wafer 118 that respectively include a cavity 126 arranged to surround each respective MEMs structure 116. In other words, a plurality of semiconductor devices 100 in the same or a similar configuration to that of the semiconductor device 100 shown in FIG. 1A may be formed on the device wafer 102, and from the device wafer 102 and the capping wafer 118.

FIG. 1B is a first top view 128 of the semiconductor device 100 illustrating the capping wafer 118, device wafer 102 and a plurality of test pads 110 formed in peripheral area of the device wafer 102. FIG. 1C is a second top view 130 of the semiconductor device 100 where the capping wafer 118 is omitted in order to show the cavity 126. Like the top view 128 in FIG. 1B, the top view 130 in FIG. 1C illustrates the device wafer 102 and a plurality of test pads 110 formed in a peripheral area of the device wafer 102. The cross-section view in FIG. 1A is taken along the line A-A′ in FIGS. 1B and 1C.

As indicated above, FIGS. 1A-1C are provided as examples. Other examples may differ from what is described with regard to FIGS. 1A-1C.

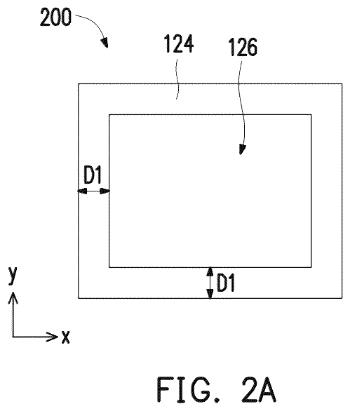

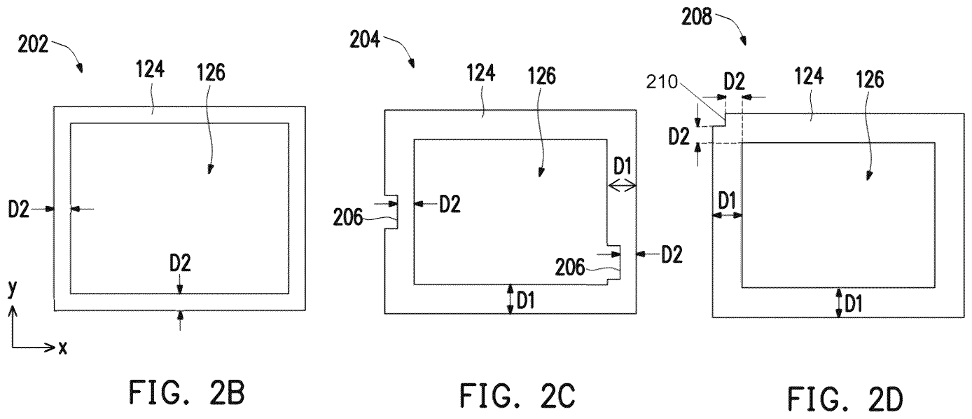

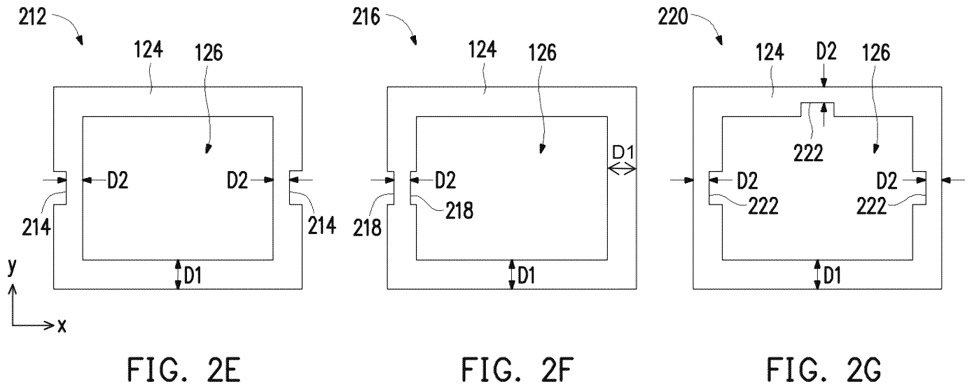

FIGS. 2A-2G are diagrams of example implementations of bonding structures 124 (e.g., seal structures) described herein. As noted herein, the width of a seal structure around a cavity may be controlled so that some cavities (e.g., cavities for MEMs devices formed on PCM dies) are more susceptible to gas leakage than the other cavities (e.g., cavities for MEMs devices formed on product dies). The greater susceptibility to gas leakage allows for a greater amount of gas leakage into the cavity to be detected in the PCM dies during testing when process variations or defects occur on a wafer. FIGS. 2A-2G show example implementations 202, 204, 208, 212, 216, and 220 where a width D2 at one or more portions of a bonding structure 124 is smaller than a width D1 of a bonding structure 124 in the example implementation 200, so that the bonding structures 124 in the example implementations 202, 204, 208, 212, 216, and 220 are more susceptible to gas leakage.

As shown in FIG. 2A, in the example implementation 200, the bonding structure 124 (e.g., seal structure), which is formed around and encloses a cavity 126 to hermetically seal the cavity 126, has a dimension D1 (e.g., width) in the x-direction and in the y-direction. The bonding structure 124 in the example implementation 200 may be formed by eutectic bonding of the first bonding layer 120 to the second bonding layer 122. In some implementations, the dimension D1 may be uniform around the entire perimeter of the bonding structure 124. The dimension D1 may be included in a range of approximately 5 microns to approximately 100 microns. However, other values and ranges are within the scope of the present disclosure.

As shown in FIG. 2B, in the example implementation 202, the bonding structure 124 (e.g., seal structure), which is formed around and encloses a cavity 126 to hermetically seal the cavity 126, has a dimension D2 (e.g., width) in the x-direction and in the y-direction. The bonding structure 124 in the example implementation 202 may be formed by eutectic bonding of the first bonding layer 120 to the second bonding layer 122. In the example implementation 202, the dimension D2 is uniform around the entire perimeter of the bonding structure 124, and is smaller than the dimension D1 in the example implementation 200.

As shown in FIG. 2C, in the example implementation 204, the bonding structure 124 (e.g., seal structure) is formed around and encloses a cavity 126 to hermetically seal the cavity 126. Some portions of the bonding structure 124 have the dimension D1 (e.g., width) in the x-direction and in the y-direction, while other portions of the bonding structure 124 have the dimension D2 in the x-direction (e.g., width). The bonding structure 124 in the example implementation 204 may be formed by eutectic bonding of the first bonding layer 120 to the second bonding layer 122. In the example implementation 204, the portions of the bonding structure 124 having the dimension D2 are recessed portions 206 of the bonding structure 124, where the dimension D2 is smaller than the dimension D1 in the example implementation 200, and in remaining portions of the bonding structure 124. The recessed portions 206 are asymmetrically distributed at different points around the perimeter of the bonding structure 124. One of the recessed portions 206 faces away from the cavity 126, while another of the recessed portions 206 faces the cavity 126. Although two recessed portions 206 are shown, in some implementations, there may be more or less than two recessed portions 206 in the bonding structure 124.

As shown in FIG. 2D, in the example implementation 208, the bonding structure 124 (e.g., seal structure) is formed around and encloses a cavity 126 to hermetically seal the cavity 126. Some portions of the bonding structure 124 have the dimension D1 (e.g., width) in the x-direction and in the y-direction, while a recessed corner portion 210 of the bonding structure 124 has the dimension D2 (e.g., width) in the x-direction and in the y-direction. The bonding structure 124 in the example implementation 208 may be formed by eutectic bonding of the first bonding layer 120 to the second bonding layer 122. In the example implementation 208, the dimension D2 is smaller than the dimension D1 in the example implementation 200, and in remaining portions of the bonding structure 124. The recessed corner portion 210 faces away from the cavity 126. Alternatively, the recessed corner portions may face the cavity 126. Although one recessed corner portion 210 is shown, in some implementations, there may be more than one recessed corner portion 210 in the bonding structure 124.

As shown in FIG. 2E, in the example implementation 212, the bonding structure 124 (e.g., seal structure) is formed around and encloses a cavity 126 to hermetically seal the cavity 126. Some portions of the bonding structure 124 have the dimension D1 (e.g., width) in the x-direction and in the y-direction, while other portions of the bonding structure 124 have the dimension D2 in the x-direction (e.g., width). The bonding structure 124 in the example implementation 212 may be formed by eutectic bonding of the first bonding layer 120 to the second bonding layer 122. In the example implementation 212, the portions of the bonding structure 124 having the dimension D2 are recessed portions 214 of the bonding structure 124, where the dimension D2 is smaller than the dimension D1 in the example implementation 200, and in remaining portions of the bonding structure 124. The recessed portions 214 are symmetrically distributed at opposite points on the perimeter of the bonding structure 124. One of the recessed portions 214 faces away from the cavity 126, while another of the recessed portions 214 faces the cavity 126. Although two recessed portions 214 are shown, in some implementations, there may be more than two recessed portions 214 which are symmetrically distributed in the bonding structure 124.

As shown in FIG. 2F, in the example implementation 216, the bonding structure 124 (e.g., seal structure) is formed around and encloses a cavity 126 to hermetically seal the cavity 126. Some portions of the bonding structure 124 have the dimension D1 (e.g., width) in the x-direction and in the y-direction, while another portion of the bonding structure 124 has the dimension D2 in the x-direction (e.g., width). The bonding structure 124 in the example implementation 216 may be formed by eutectic bonding of the first bonding layer 120 to the second bonding layer 122. In the example implementation 216, the portion of the bonding structure 124 having the dimension D2 is a recessed portions 218 of the bonding structure 124, where the dimension D2 is smaller than the dimension D1 in the example implementation 200, and in remaining portions of the bonding structure 124. The recessed portion includes a first side facing away from the cavity 126, and a second side facing the cavity 126. Although one recessed portion 218 is shown, in some implementations, there may be more than one recessed portion 218 in the bonding structure 124.

As shown in FIG. 2G, in the example implementation 220, the bonding structure 124 (e.g., seal structure) is formed around and encloses a cavity 126 to hermetically seal the cavity 126. Some portions of the bonding structure 124 have the dimension D1 (e.g., width) in the x-direction and in the y-direction, while other portions of the bonding structure 124 have the dimension D2 (e.g., width) in the x-direction and in the y-direction. The bonding structure 124 in the example implementation 220 may be formed by eutectic bonding of the first bonding layer 120 to the second bonding layer 122. In the example implementation 220, the portions of the bonding structure 124 having the dimension D2 are recessed portions 222 of the bonding structure 124, where the dimension D2 is smaller than the dimension D1 in the example implementation 200, and in remaining portions of the bonding structure 124. The recessed portions 222 are distributed at different points around the perimeter of the bonding structure 124. Each of the recessed portions 222 faces the cavity 126. Although three recessed portions 222 are shown, in some implementations, there may be more or fewer than three recessed portions 222 in the bonding structure 124.

In the example implementations 202, 204, 208, 212, 216, and 220, a difference between the dimension D2 and the dimension D1 may be included in a range of approximately 5% to approximately 10%. However, other values and ranges are within the scope of the present disclosure. If the difference between the dimension D2 and the dimension D1 is less than approximately 5%, there may be insufficient susceptibility to gas leakage for the bonding structures 124 in the example implementations 202, 204, 208, 212, 216, and 220. As a result, during testing to determine whether process variations and/or defects have occurred on a wafer, gas leakage may be undetectable in PCM dies including the bonding structures 124 in the example implementations 202, 204, 208, 212, 216, and 220. If the difference between the dimension D2 and the dimension D1 is greater than approximately 10%, the bonding structures 124 in the example implementations 202, 204, 208, 212, 216, and 220 may be overly susceptible to gas leakage. As a result, during testing to determine whether process variations and/or defects have occurred on a wafer, gas leakage may occur too easily in PCM dies including the bonding structures 124 in the example implementations 202, 204, 208, 212, 216, and 220, so that false conclusions of process variations and/or defects may be generated. In some implementations, the dimension D2 is included in the range of approximately 90% of the dimension D1 to approximately 95% of the dimension D1. However, other values and ranges are within the scope of the present disclosure.

As indicated above, FIGS. 2A-2G are provided as examples. Other examples may differ from what is described with regard to FIGS. 2A-2G.

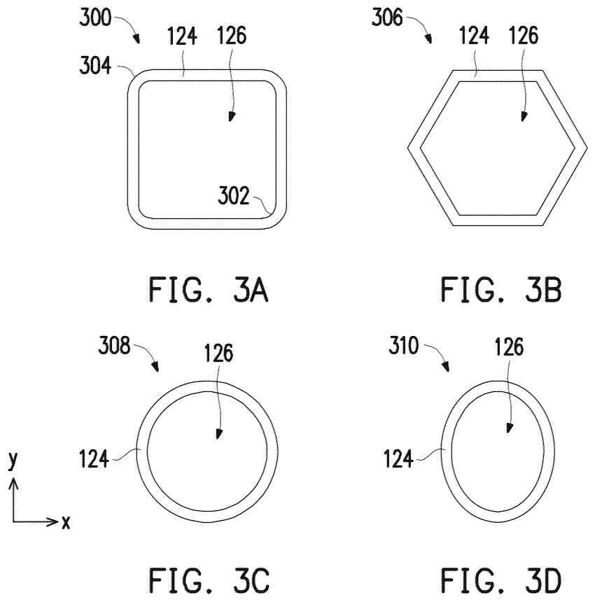

FIGS. 3A-3D are diagrams of example implementations of cavity structures described herein. As shown in the example implementation 300 in FIG. 3A, the bonding structure 124 (e.g., seal structure) is formed around and encloses a cavity 126 to hermetically seal the cavity 126. The bonding structure 124 and the cavity 126 may have a quadrilateral shape (e.g., square, rectangle, etc.). The bonding structure 124 also may have rounded internal corners 302 and rounded external corners 304. In some implementations, the corners of the bonding structure 124 may be square.

As shown in the example implementation 306 in FIG. 3B, the bonding structure 124 (e.g., seal structure) is formed around and encloses a cavity 126 to hermetically seal the cavity 126. The bonding structure 124 and the cavity 126 may have a high-order (i.e., more than four sides) polygon shape (e.g., pentagon, hexagon, etc.).

As shown in the example implementation 308 in FIG. 3C, the bonding structure 124 (e.g., seal structure) is formed around and encloses a cavity 126 to hermetically seal the cavity 126. The bonding structure 124 and the cavity 126 may have a circular shape.

As shown in the example implementation 310 in FIG. 3C, the bonding structure 124 (e.g., seal structure) is formed around and encloses a cavity 126 to hermetically seal the cavity 126. The bonding structure 124 and the cavity 126 may have an oval shape.

As indicated above, FIGS. 3A-3D are provided as examples. Other examples may differ from what is described with regard to FIGS. 3A-3D.

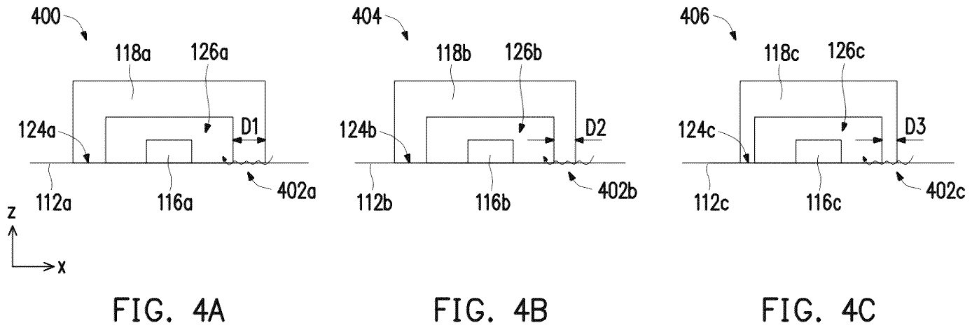

FIGS. 4A-4C are diagrams of example semiconductor devices described herein. As shown in FIG. 4A, the example semiconductor device 400 includes a first semiconductor layer portion 112a, a first MEMs structure 116a, a first capping wafer portion 118a, a first bonding structure 124a, and a first cavity 126a. The first bonding structure 124a has a dimension D1. A depiction of gas leakage 402a through the first bonding structure 124a into the first cavity 126a is shown.

As shown in FIG. 4B, the example semiconductor device 404 includes a second semiconductor layer portion 112b, a second MEMs structure 116b, a second capping wafer portion 118b, a second bonding structure 124b, and a second cavity 126b. The second bonding structure 124b has a dimension D2, which is less than the dimension D1. A depiction of gas leakage 402b through the second bonding structure 124b into the second cavity 126b is shown.

As shown in FIG. 4C, the example semiconductor device 406 includes a third semiconductor layer portion 112c, a third MEMs structure 116c, a third capping wafer portion 118c, a third bonding structure 124c, and a third cavity 126c. The third bonding structure 124c has a dimension D3, which is less than the dimension D1, and less than the dimension D2. A depiction of gas leakage 402c through the third bonding structure 124c into the third cavity 126c is shown.

In some implementations, the semiconductor devices 400, 404, and 406 are MEMs devices formed on the same device wafer (e.g., device wafer 102), and are formed from different portions of the same semiconductor layer (e.g., semiconductor layer 112), and different portions of the same capping wafer (e.g., capping wafer 118). Alternatively, the semiconductor devices 400, 404, and 406 may be formed on the same device wafer (e.g., device wafer 102), and formed from different semiconductor layers and/or different capping wafers. In some implementations, the dimension D2 is less than approximately 95% of the dimension D1, and the dimension D3 is less than approximately 95% of the dimension D1.

The first MEMs structure 116a, the second MEMs structure 116b, and third MEMs structure 116c may each include a resonator. A resonator or other pressure sensitive device in each of the first cavity 126a, the second cavity 126b, and the third cavity 126c may be used as a sensor to detect pressure changes. For example, a quality factor (Q) of a pressure sensitive device (e.g., resonator) may be dependent on a vacuum pressure in a cavity in which the pressure sensitive device is located. The quality factor of a resonator corresponds to a ratio of the initial energy stored in the resonator to the energy lost in an oscillation cycle of the resonator. Gas leakages 402a, 402b, and 402c may cause the vacuum pressure (e.g., negative pressure) in the first, second, and/or third cavities 126a-126c to degrade (e.g., equalize to the ambient pressure outside the cavity). As a result, the damping of the resonator is increased, thereby resulting in greater energy loss in (and therefore, reduced quality factor) per oscillation of the resonator. Outgassing (e.g., the flow of gas out of a cavity that may have been trapped in the cavity during a fabrication process) may also cause a change in pressure in a cavity.

In some implementations, a width of a bonding structure (e.g., dimension D1 of first bonding structure 124a) around the cavity (e.g., first cavity 126a) may be sufficiently large so that the time for gas to diffuse into the cavity will be long enough to allow for unimpeded operation of a MEMS device. In the case of the first bonding structure 124a with the dimension D1, if a gas leakage path occurs through the first bonding structure 124a, the leakage amount may be too small to detect over a given period of time because of the dimension D1 (e.g., width) of the first bonding structure 124a. For example, since diffusion of gas occurs over time, after a certain time, leakage starts to change the pressure in the cavity, which changes the quality factor of the MEMS device. However, because the amount of leakage over time is small, the change in the quality factor over time may not be sufficiently large to detect the gas leakage 402a into the first cavity 126a because the increase in damping amount of the MEMS device over time may be small. As a result of the leakage being undetected, the leakage may degrade the quality of the vacuum in the cavity, thereby reducing the sensitivity of the MEMS device, decreasing the accuracy of the MEMS device, and/or causing the MEMS device to fail. The first cavity 126a may have a shape described in connection with the example implementations 300, 306, 308, or 310 in FIGS. 3A-3C, or another shape.

In the case of the second bonding structure 124b with the dimension D2, the width of the second bonding structure around the second cavity 126b is smaller than the width of the first bonding structure 124a so that the second cavity 126b is more susceptible to gas leakage than the first cavity 126a. The greater susceptibility to gas leakage allows for a greater amount of gas leakage into the second cavity 126b to be detected during testing when process variations or defects occur on a wafer. In more detail, the dimension D2 (e.g., width) of the second bonding structure 124b enables measurement of a change in the cavity pressure of the second cavity 126b to be performed between a first time T₀ and a second time T₁ when a measurement of a change in the cavity pressure of the first cavity 126a may be too small to be detected. The change in cavity pressure may cause the quality factor (Q) of the pressure sensitive device (e.g., resonator) in the second cavity 126b to change by a greater amount than the pressure sensitive device (e.g., resonator) in the first cavity 126a, thereby enabling leakage to be more easily detectable in the semiconductor device 404. The dimension D2 of the second bonding structure 124b may be achieved through one or more of the arrangements described in connection with the example implementations 202, 204, 208, 212, 216, and/or 220 in FIGS. 2B-2G, or another arrangement. In addition, the second cavity 126b may have a shape described in connection with the example implementations 300, 306, 308, or 310 in FIGS. 3A-3C, or another shape.

In the case of the third bonding structure 124c with the dimension D3, the width of the third bonding structure around the third cavity 126c is smaller than the widths of the first bonding structure 124a and of the second bonding structure 124b, so that the third cavity 126c is more susceptible to gas leakage than the first cavity 126a, and the second cavity 126b. The greater susceptibility to gas leakage allows for a greater amount of gas leakage into the third cavity 126c to be detected during testing when process variations or defects occur on a wafer. In more detail, the dimension D3 (e.g., width) of the third bonding structure 124b enables measurement of a change in the cavity pressure of the third cavity 126c to be performed between a first time T₀ and a second time T₁ when a measurement of a change in the cavity pressure of the first and/or second cavities 126a and 126b may be too small to be detected. The change in cavity pressure may cause the quality factor of the pressure sensitive device (e.g., resonator) in the third cavity 126c to change by a greater amount than the pressure sensitive device (e.g., resonator) in the first cavity 126a and/or the second cavity 126b, thereby enabling leakage to be more easily detectable in the semiconductor device 406. The dimension D3 of the third bonding structure 124c may be achieved through one or more of the arrangements described in connection with dimension D2 in the example implementations 202, 204, 208, 212, 216, and/or 220 in FIGS. 2B-2G, or another arrangement. In addition, the third cavity 126c may have a shape described in connection with the example implementations 300, 306, 308, or 310 in FIGS. 3A-3C, or another shape. A semiconductor device 400, 404, and/or 406 may have the same or a similar configuration to the semiconductor device 100.

As indicated above, FIGS. 4A-4C are provided as examples. Other examples may differ from what is described with regard to FIGS. 4A-4C.

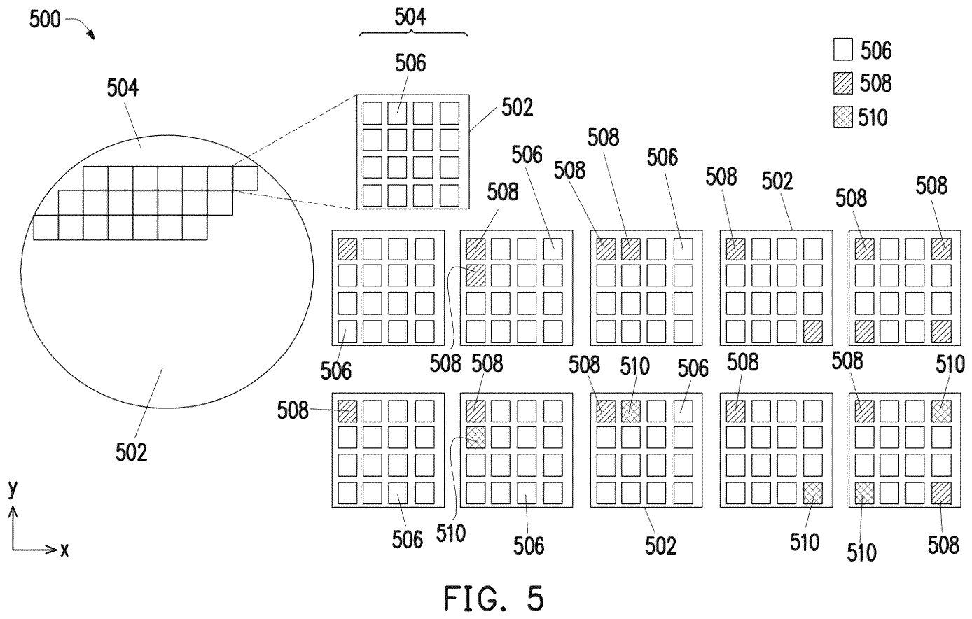

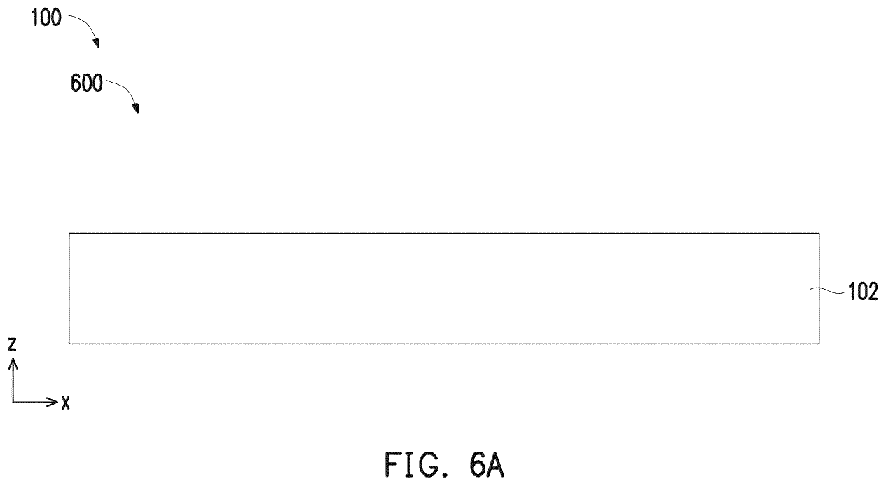

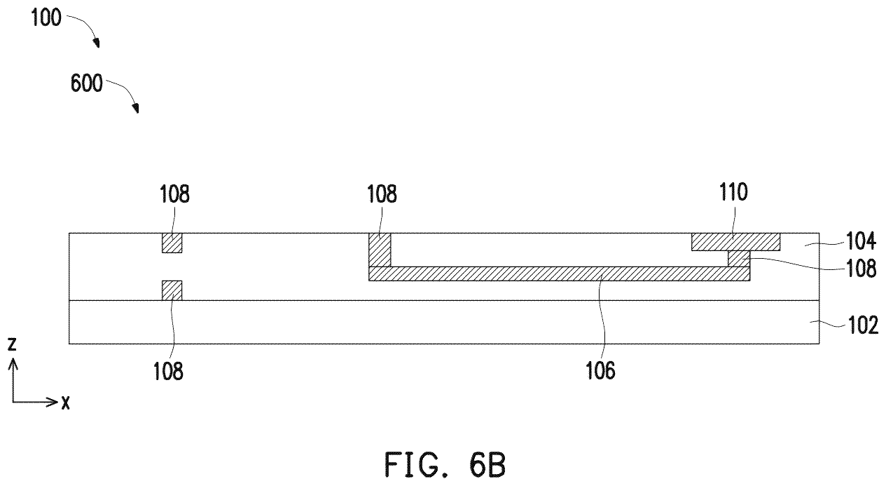

FIG. 5 is a diagram of an example implementation of a semiconductor structure described herein. As shown in the example implementation 500, a semiconductor structure includes a semiconductor wafer 502 (e.g., a device wafer). The semiconductor wafer 502 includes a plurality of die groupings 504, each die grouping 504 including a plurality of semiconductor dies. A semiconductor die may be a product die 506, a first PCM die 508, or a second PCM die 510. A semiconductor die may include a semiconductor device 100, 400, 404, and/or 406.

A die grouping 504 on the semiconductor wafer 502 may include a plurality of product dies 506. In addition to the plurality of product dies 506, a die grouping 504 may include one or more first PCM dies 508 and/or one or more second PCM dies 510. In some implementations, a product die 506 includes a semiconductor device 100 or 400 with a bonding structure 124 or 124a having the first dimension D1, a first PCM die 508 includes a semiconductor device 100 or 404 with a bonding structure 124 or 124b having the second dimension D2, and a second PCM die 510 includes a semiconductor device 100 or 406 with a bonding structure 124 or 124b having the second dimension D3.

As shown in FIG. 5, some die groupings 504 include a plurality of product dies 506 and one first PCM die 508 adjacent to one or more product dies 506. Some die groupings 504 include a plurality of product dies 506 and more than one first PCM die 508. In some implementations, the first PCM dies 508 may be adjacent to each other or in different locations with one or more of the plurality of product dies 506 between the first PCM dies 508. For example, the first PCM dies 508 may be in opposing corners with product dies 506 between the first PCM dies 508. Some die groupings 504 include a plurality of product dies 506, one or more first PCM dies 508, and one or more second PCM dies 510. In some implementations, the first and second PCM dies 508 and 510 are adjacent to each other or in different locations with one or more of the plurality of product dies 506 between a first PCM die 508 and a second PCM die 510. For example, a first PCM die 508 and a second PCM die 510 may be in opposing corners with product dies 506 between the first PCM die 508 and the second PCM die 510.

Product dies 506 that include MEMS devices are manufactured on a semiconductor wafer 502 along with one or more first PCM dies 508 and/or second PCM dies 510. The width (e.g., dimension D2 or dimension D3) of a bond structure 124 around a cavity 126 in the one or more first PCM dies 508 and/or second PCM dies 510 on the semiconductor wafer is controlled so that the cavities 126 of the first PCM dies 508 and/or second PCM dies 510 are more susceptible to gas leakage than the cavities 126 of the product dies 506. The greater susceptibility to gas leakage allows for a greater amount of gas leakage into the cavity to be detected in the first PCM dies 508 and/or second PCM dies 510 during testing when process variations or defects occur on the semiconductor wafer 502. In more detail, the width (e.g., dimension D2 or dimension D3) of a bond structure 124 for a first PCM die 508 and/or a second PCM die 510 enables measurement of a change in the cavity pressure of a first PCM die 508 and/or a second PCM die 510 to be performed between a first time T₀ and a second time T₁. The change in cavity pressure may cause the quality factor (Q) of the first PCM die 508 and/or the second PCM die 510 to change by a greater amount than the product dies 506, thereby enabling leakage to be more easily detectable in the first PCM dies 508 and/or the second PCM dies 510 without subjecting the product dies 506 to damaging levels of stress.

The bond structures 124 for the first PCM dies 508 and/or the second PCM dies 510 may have one or more of the arrangements described in connection with the example implementations 202, 204, 208, 212, 216, and/or 220 in FIGS. 2B-2G, or another arrangement. In addition, the cavities 126 for the first PCM dies 508 and/or the second PCM dies 510 may have a shape described in connection with the example implementations 300, 306, 308, or 310 in FIGS. 3A-3C, or another shape. The quantity and locations of the first PCM dies 508, the second PCM dies 510, and the product dies on a semiconductor wafer 502 can vary.

As indicated above, FIG. 5 is provided as an example. Other examples may differ from what is described with regard to FIG. 5.

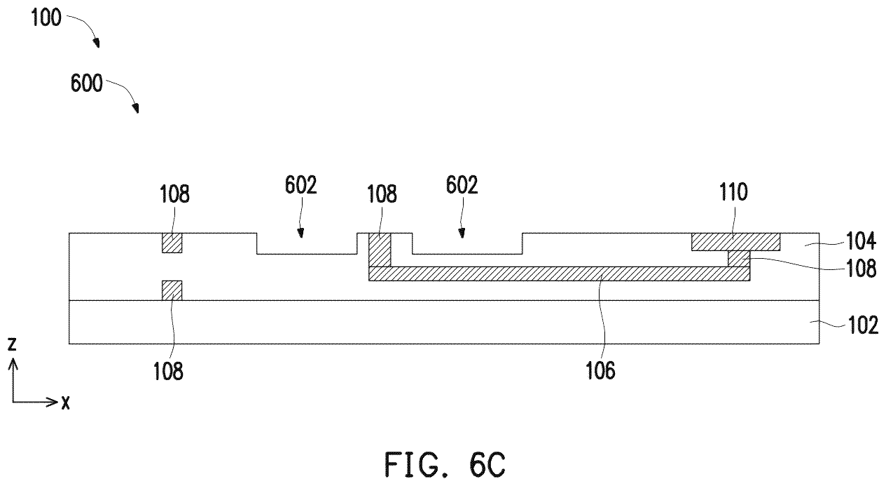

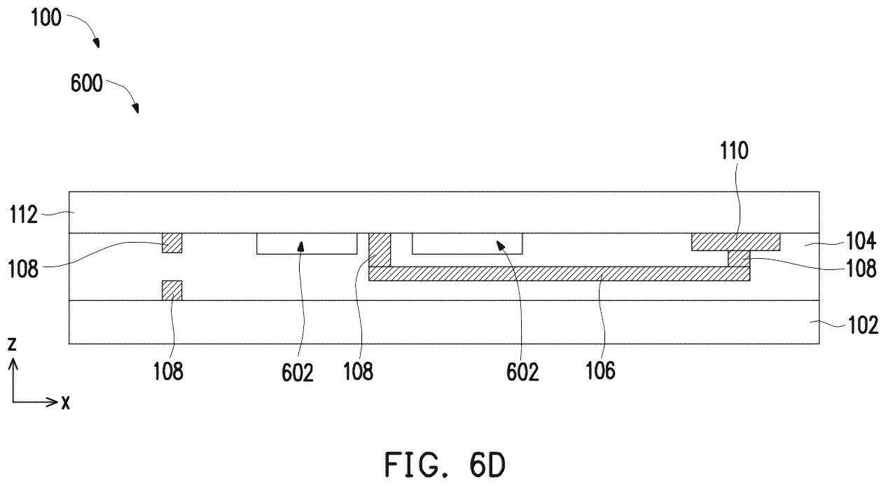

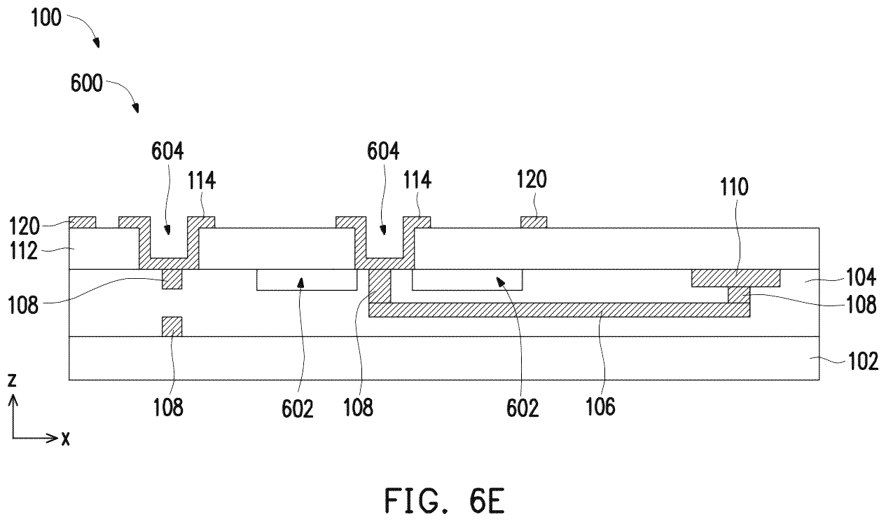

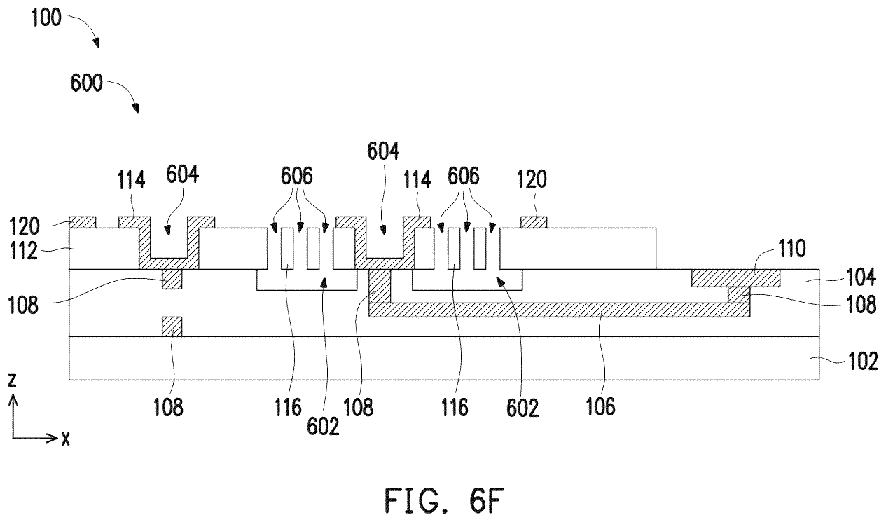

FIGS. 6A-6F are diagrams of an example implementation 600 of forming a device wafer 102 of a semiconductor device 100 described herein. In some implementations, one or more semiconductor processing tools may perform one or more of the techniques and/or processes described in connection with FIGS. 6A-6F. In some implementations, one or more of the techniques and/or processes described in connection with FIGS. 6A-6F may be performed by other semiconductor processing tools.

As shown in FIG. 6A, the device wafer 102 is provided. The device wafer 102 may include a substrate provided in the form of a semiconductor wafer such as a silicon (Si) wafer, an SOI wafer, and/or another type of semiconductor work piece. The semiconductor device 100 may be formed on the semiconductor wafer with other semiconductor devices.

As shown in FIG. 6B, a deposition tool is used to deposit one or more dielectric layers (e.g., ILD layers and/or ESLs) of the interconnect layer 104 over and/or on the device wafer 102. A deposition tool may be used to deposit the one or more dielectric layers of the interconnect layer 104 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the one or more dielectric layers of the interconnect layer 104 after the one or more dielectric layers of the interconnect layer 104 are deposited.

A deposition tool, an exposure tool, a developer tool, an etch tool, a planarization tool, a plating tool, and/or another semiconductor processing tool may be used to perform various operations to form the metallization structures 106, to form the interconnect structures 108, and to form the test pad(s) 110 in the interconnect layer 104 of the semiconductor device 100.

The metallization structures 106, interconnect structures 108, and test pad(s) 110 may be formed in recesses in the one or more dielectric layers of the interconnect layer 104. In some implementations, a pattern in a photoresist layer is used to etch the one or more dielectric layers to form the recesses. In these implementations, a deposition tool may be used to form the photoresist layer on the interconnect layer 104. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the one or more dielectric layers of the interconnect layer 104 based on a pattern to form the recesses.

One or more deposition tools may be used to deposit the metallization structures 106, interconnect structures 108, and/or test pad(s) 110 in the recesses using a PVD technique, an ALD technique, a CVD technique, an electroplating technique (e.g., an electro-chemical plating technique), and/or another suitable deposition technique. In some implementations, a planarization tool may be used to planarize the metallization structures 106, interconnect structures 108, and/or test pad(s) 110 after the metallization structures 106, interconnect structures 108, and/or test pad(s) 110 are deposited.

Turning to FIG. 6C, a pattern in a photoresist layer is used to etch the one or more dielectric layers in the interconnect layer 104 to form MEMs structure cavities 602 in the interconnect layer 104. In some implementations, a deposition tool may be used to form the photoresist layer on the interconnect layer 104. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the one or more dielectric layers of the interconnect layer 104 based on a pattern to form the MEMs structure cavities 602. In some implementations, a depth of the cavities in the z-direction is included in the range of approximately 0.5 microns to approximately 30 microns. However, other values and ranges are within the scope of the present disclosure.

As shown in FIG. 6D, the semiconductor layer 112 is fusion bonded to the interconnect layer 104. In this case, a dielectric material of the interconnect layer 104 where fusion bonding occurs may include an oxide material such as a silicon oxide (e.g., SiOₓ, such as SiO₂), or another type of oxide material. In particular, a bonding tool may fusion bond the semiconductor layer 112 to the interconnect layer 104. The fusion bond may form a hermetic seal between the semiconductor layer 112 and the interconnect layer 104.

Fusion bonding the semiconductor layer 112 and the interconnect layer 104 may include pressing the semiconductor layer 112 against the interconnect layer 104 and performing an annealing process to cause the semiconductor layer 112 and the interconnect layer 104 to be bonded together due to atomic attraction forces. The fusion bonding process may be used to bond silicon (Si) to a silicon oxide (e.g., SiOₓ, such as SiO₂).

In some implementations, a planarization and/or a wafer grinding tool may be used to perform a grinding operation on the top surface of the semiconductor layer 112 to mechanically grind silicon material away from the semiconductor layer 112. The grinding operation reduces the thickness of the semiconductor layer 112 so that the resulting thickness of the semiconductor layer 112 in the z-direction may be included in the range of approximately 1 micron to approximately 100 microns. However, other values and ranges are within the scope of the present disclosure. The semiconductor layer 112 may be thinned to reduce the processing time and/or etchant consumption of an etch operation to remove portions of the semiconductor layer 112.

As shown in FIG. 6E, recesses 604 are formed in the semiconductor layer 112 to expose top surfaces of interconnect structures 108. The contact structures 114 may be formed in the recesses 604. In some implementations, an etch tool may be used to etch a dielectric masking layer based on a pattern corresponding to the locations of the recesses 604 in a photoresist layer, to transfer the pattern to the dielectric masking layer. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

Following formation of the recesses 604, the conductive material of the contact structures 114 is deposited on sidewalls and bottom surfaces of the recesses 604, on a top surface of the semiconductor layer 112, and on exposed top surfaces of the interconnect structures 108 using a conformal deposition technique, such as, for example, CVD or ALD.

As further shown in FIG. 6E, the first bonding layer 120 (e.g., aluminum (Al) or gold (Au)) is deposited on a top surface of the semiconductor layer 112. One or more deposition tools may be used to deposit the first bonding layer 120 using a PVD technique, an ALD technique, a CVD technique, an electroplating technique (e.g., an electro-chemical plating technique), and/or another suitable deposition technique. Portions of the deposited first bonding layer 120 may be removed in an etching operation to form the first bonding layer 120 into a pattern corresponding to a shape of the bonding structure 124. In some implementations, a hard mask layer may be formed on portions of the first bonding layer 120 corresponding to where the first bonding layer 120 is to remain. In some implementations, for a MEMs device on a product die 506, the first bonding layer 120 may be formed into a pattern incorporating the features of the example implementation 200 of a bonding structure 124 having the uniform dimension D1. In some implementations, for a MEMs device on a first PCM die 508 or on a second PCM die 510, the first bonding layer 120 may be formed into a pattern incorporating the features of the example implementations 202, 204, 208, 212, 216, and/or 220 of a bonding structure 124, which may include the uniform dimension D2 (or D3), or include one or more of the recessed portions 206, 210, 214, 218, and/or 222 to result in the dimension D2 (or D3) for portions of the bonding structure 124.

As shown in FIG. 6F, one or more semiconductor processing tools may form the MEMS structure(s) 116. A deposition tool may deposit a photoresist layer on portions of the semiconductor layer 112, on the contact structures 114, and on the first bonding layer 120 by a spin coating operation. An exposure tool may form a pattern in the photoresist layer by exposing the photoresist layer to a radiation source to transfer the pattern from a photomask to the photoresist layer. A developer tool may perform a development operation that includes one or more techniques to develop the pattern in the photoresist layer. An etching tool may etch through one or more portions of the semiconductor layer 112 to form cavities 606 in the semiconductor layer 112, which are part of the MEMS structure(s) 116. In some implementations, a solvent or chemical stripper is used to remove the remaining portions of the photoresist layer. In some implementations, a plasma ashing process is used to remove the remaining portions of the photoresist layer. In these examples, a plasma source is used to form a plasma of oxygen ions or fluorine ions to react with the photoresist material. The reaction between the ions in the plasma and the photoresist material causes the photoresist material to form an ash, which is removed using a vacuum pump.

As indicated above, FIGS. 6A-6F are provided as examples. Other examples may differ from what is described with regard to FIGS. 6A-6F.

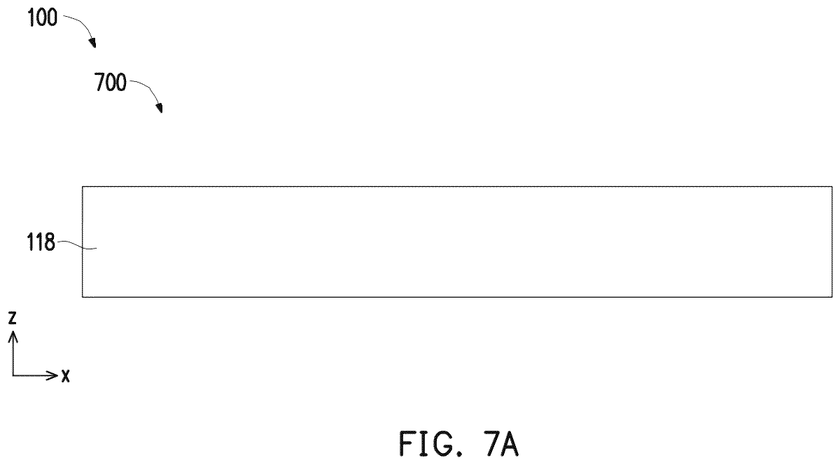

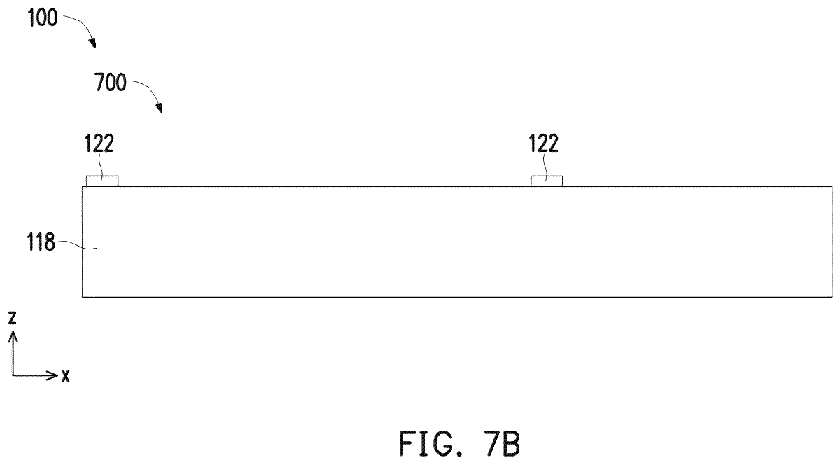

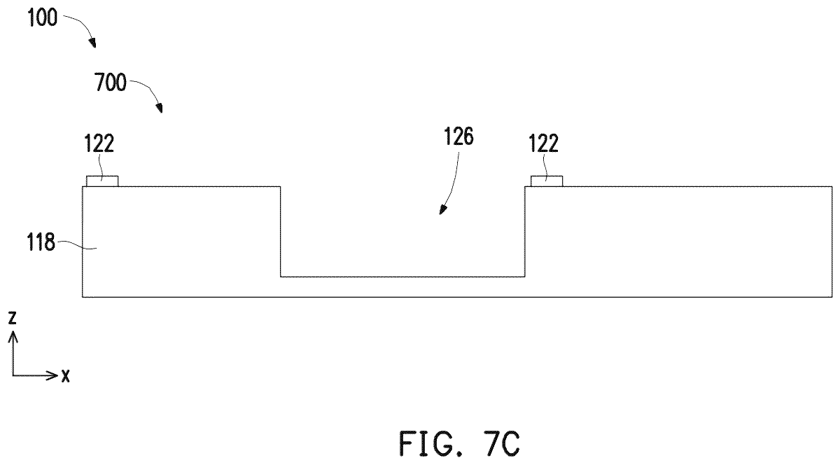

FIGS. 7A-7C are diagrams of an example implementation 700 of forming a capping wafer 118 of a semiconductor device 100 described herein. In some implementations, one or more semiconductor processing tools may perform one or more of the techniques and/or processes described in connection with FIGS. 7A-7C. In some implementations, one or more of the techniques and/or processes described in connection with FIGS. 7A-7C may be performed by other semiconductor processing tools.

As shown in FIG. 7A, the capping wafer 118 is provided. The capping wafer 118 may include a substrate provided in the form of a semiconductor wafer such as a silicon (Si) wafer, and/or another type of semiconductor work piece.

Turning to FIG. 7B, the second bonding layer 122 (e.g., germanium (Ge) or silicon (Si)) is deposited on a top surface of the capping wafer 118. One or more deposition tools may be used to deposit the second bonding layer 122 using a PVD technique, an ALD technique, a CVD technique, an electroplating technique (e.g., an electro-chemical plating technique), and/or another suitable deposition technique. Portions of the deposited second bonding layer 122 may be removed in an etching operation to form the second bonding layer 122 into a pattern corresponding to a shape of the bonding structure 124. In some implementations, a hard mask layer may be formed on portions of the second bonding layer 122 corresponding to where the second bonding layer 122 is to remain. In some implementations, for a MEMs device on a product die 506, the second bonding layer 122 may be formed into a pattern incorporating the features of the example implementation 200 of a bonding structure 124 having the uniform dimension D1. In some implementations, for a MEMs device on a first PCM die 508 or on a second PCM die 510, the second bonding layer 122 may be formed into a pattern incorporating the features of the example implementations 202, 204, 208, 212, 216, and/or 220 of a bonding structure 124, which may include the uniform dimension D2 (or D3), or include one or more of the recessed portions 206, 210, 214, 218, and/or 222 to result in the dimension D2 (or D3) for portions of the bonding structure 124.

As shown in FIG. 7C, one or more semiconductor processing tools may form the cavity 126 in the capping wafer 118. A deposition tool may deposit a photoresist layer on portions of the capping wafer, and on the second bonding layer 122 by a spin coating operation. An exposure tool may form a pattern in the photoresist layer by exposing the photoresist layer to a radiation source to transfer the pattern from a photomask to the photoresist layer. A developer tool may perform a development operation that includes one or more techniques to develop the pattern in the photoresist layer. An etching tool may etch a portion of the capping wafer 118 corresponding to where the cavity 126 is to be formed to form the cavity 126 in the capping wafer. In some implementations, a solvent or chemical stripper is used to remove the remaining portions of the photoresist layer. In some implementations, a plasma ashing process is used to remove the remaining portions of the photoresist layer. In these examples, a plasma source is used to form a plasma of oxygen ions or fluorine ions to react with the photoresist material. The reaction between the ions in the plasma and the photoresist material causes the photoresist material to form an ash, which is removed using a vacuum pump.

In some implementations, the depth of the cavity in the z-direction may be included in the range of approximately 1 micron to approximately 200 microns. However, other values and ranges are within the scope of the present disclosure.

As indicated above, FIGS. 7A-7C are provided as examples. Other examples may differ from what is described with regard to FIGS. 7A-7C.

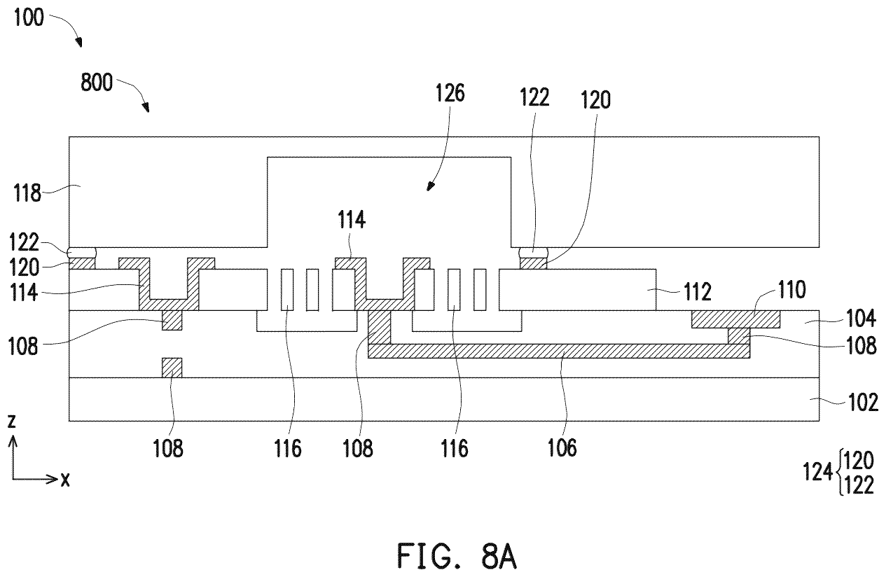

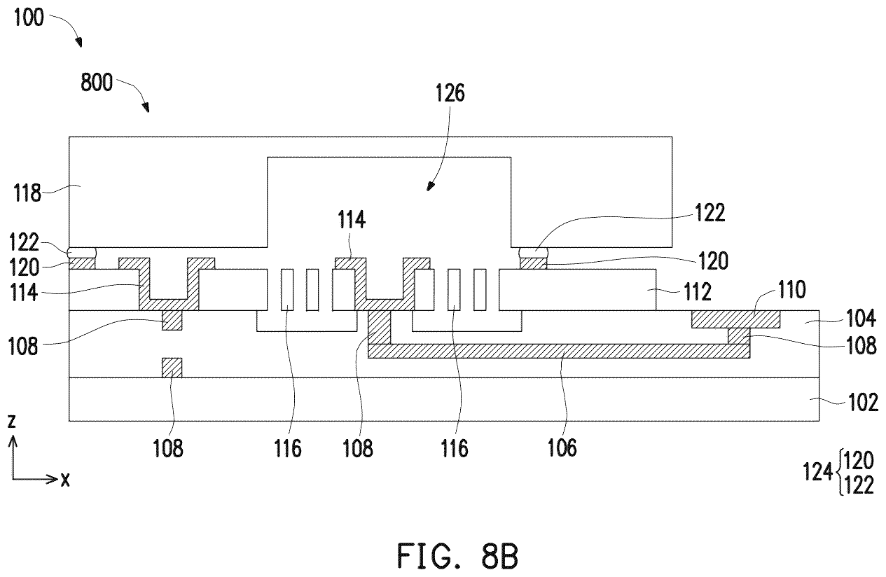

FIGS. 8A and 8B are diagrams of an example implementation 800 of bonding and dicing wafers of a semiconductor device 100 described herein. In some implementations, one or more semiconductor processing tools may perform one or more of the techniques and/or processes described in connection with FIGS. 8A and 8B. In some implementations, one or more of the techniques and/or processes described in connection with FIGS. 8A and 8B may be performed by other semiconductor processing tools.

As shown in FIG. 8A, the device wafer 102 and the capping wafer 118 may be bonded via the semiconductor layer 112. A semiconductor processing tool (e.g., a bonding tool) may bond the device wafer 102 and the capping wafer 118 by performing a eutectic bonding process to form a eutectic bond between the first bonding layer 120 (e.g., metal bonding layer) of the device wafer 102 and the second bonding layer 122 (e.g., germanium (Ge) bonding layer) of the capping wafer 118. Eutectic bonding may be referred to as a low-temperature bonding in that the bonds between the materials of the first bonding layer 120 and the second bonding layer 122 are formed at a temperature below the melting temperature of the materials of the first bonding layer 120 and the second bonding layer 122. The bonding tool may heat the device wafer 102 and the capping wafer 118 such that eutectic bonds are formed between the first bonding layer 120 and the second bonding layer 122. For example, if the first bonding layer 120 is formed of an aluminum material, the bonding tool may heat the device wafer 102 and the capping wafer 118 such that the first bonding layer 120 and the second bonding layer 122 are heated to approximately 425 degrees Celsius to form the eutectic bonds. In some implementations, the eutectic bonding process may be combined with an annealing process (e.g., where the capping wafer 118 and the device wafer 102 are heated to a high temperature of 1100 degrees Celsius or more) to reduce the stress at the bonding interfaces resulting from the eutectic bonding process.

The resulting bond structure 124 from the eutectic bonds between the device wafer 102 and the capping wafer 118 forms the cavity 126 in which the MEMS structure(s) 116 are hermitically sealed. The cavity 126 permits the MEMS structure(s) 116 (e.g., moveable MEMs structures) to freely move or actuate, and prevents foreign objects and other contamination from damaging the MEMS structure(s) 116.

As shown in FIG. 8B, the capping wafer 118 is diced to expose the test pad(s) 110 for CP and WAT testing.

As indicated above, FIGS. 8A and 8B are provided as examples. Other examples may differ from what is described with regard to FIGS. 8A and 8B.

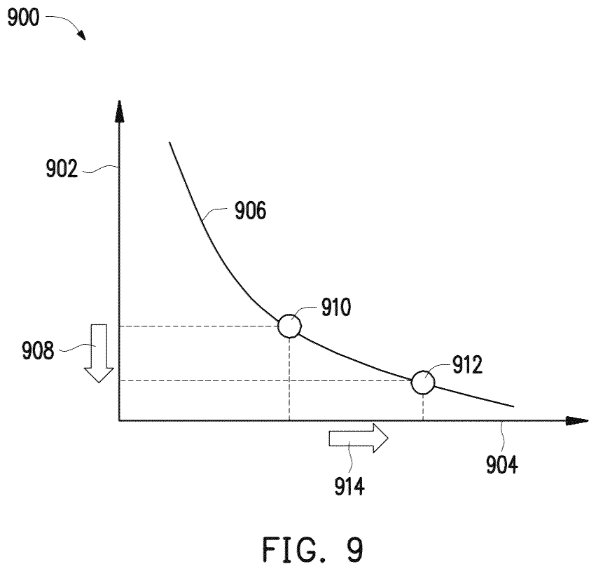

FIG. 9 is a graph 900 of quality factor (Q) as a function of pressure change. For example, a quality factor of a pressure sensitive device (e.g., resonator) in a cavity 126 may be dependent on a vacuum pressure in the cavity 126. The quality factor of a resonator corresponds to a ratio of the initial energy stored in the resonator to the energy lost in an oscillation cycle of the resonator. As the vacuum pressure (e.g., negative pressure) degrades (e.g., equalizes to the ambient pressure outside the cavity 126 due to, for example, gas leakage into the cavity 126), the damping of the resonator is increased, thereby resulting in greater energy loss in (and therefore, reduced quality factor) per oscillation of the resonator.

Referring to the graph 900, the vertical axis 902 corresponds to the quality factor and the horizontal axis 904 corresponds to pressure. The curve 906 illustrates that the quality factor decreases with an increase in pressure. For example, a decrease in the quality factor illustrated by arrow 908 between points 910 and 912 on the curve 906 corresponds to an increase in pressure, illustrated by arrow 914 between points 910 and 912.

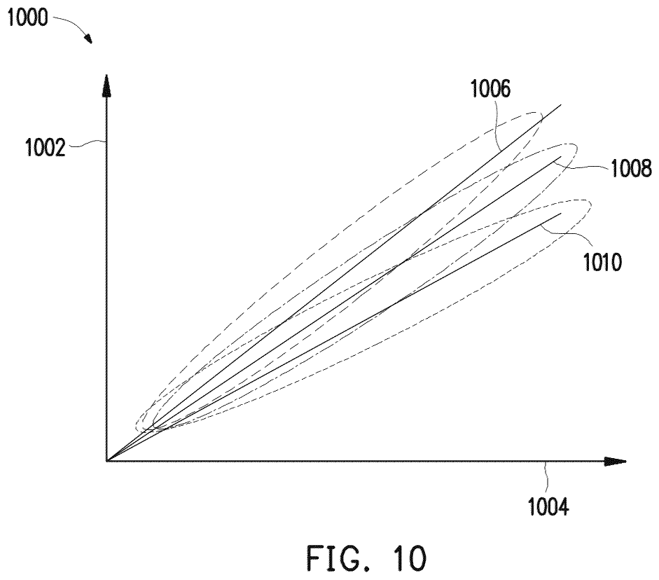

FIG. 10 is a graph 1000 of quality factor differences between a first time T₀ and a second time T₁ for a product die (e.g., product die 506) having a bond structure 124 (e.g., seal structure) with the dimension D1, a first PCM die (e.g., a first PCM die 508) having a bond structure 124 (e.g., seal structure) with the dimension D2, and a second PCM die (e.g., second PCM die 510) having a bond structure 124 (e.g., seal structure) with the dimension D3.

Referring to the graph 1000, the vertical axis 1002 corresponds to the quality factor at the second time T₁ and the horizontal axis 1004 corresponds to the quality factor at the first time T₀. The highlighted sections 1006, 1008, and 1010 respectively correspond to a ratio of the quality factor (Q) at the second time T₁ (QT₁) to the quality factor at the first time T₀ (QT₀) for the product die, first PCM die, and second PCM die. The ratio of QT₁ to QT₀ for section 1006 may be 1 or approximately 1, indicating that there is no change in quality factor (e.g., no detectable change in cavity pressure between the first time T₀ and the second time T₁) for a MEMs device having a bond structure 124 with the dimension D1. The ratio of QT₁ to QT₀ for section 1008 may be less than 1 (e.g., less than the ratio of QT₁ to QT₀ for section 1006) indicating that quality factor decreases between the first time T₀ and the second time T₁ (e.g., there is a detectable change in cavity pressure between the first time T₀ and the second time T₁) for a MEMs device having a bond structure 124 with the dimension D2. The ratio of QT₁ to QT₀ for section 1010 may be less than the ratio of QT₁ to QT₀ for section 1008, indicating that the quality factor further decreases between the first time T₀ and the second time T₁ (e.g., the change in cavity pressure between the first time T₀ and the second time T₁ has increased detectability) for a MEMs device having a bond structure 124 with the dimension D3.

The bond structures 124 with dimensions D2 and D3 enable detection of changes in cavity pressure for MEMs devices on PCM dies during testing so that issues with certain portions of a wafer where the PCM dies are located can be identified without subjecting MEMs devices on product dies to unwanted stress and/or damage.

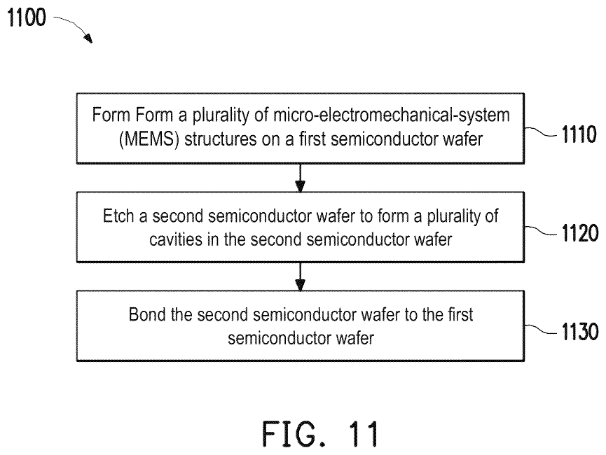

FIG. 11 is a flowchart of an example process 1100 associated with forming a semiconductor structure. In some implementations, one or more process blocks of FIG. 11 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 11, process 1100 may include forming a plurality of MEMS structures on a first semiconductor wafer (block 1110). For example, one or more semiconductor processing tools may be used to form a plurality of MEMS structures (e.g., MEMS structures 116) on a first semiconductor wafer (e.g., device wafer 102), as described herein.

As further shown in FIG. 11, process 1100 may include etching a second semiconductor wafer to form a plurality of cavities in the second semiconductor wafer (block 1120). For example, one or more semiconductor processing tools may be used to etch a second semiconductor wafer (e.g., capping wafer 118) to form a plurality of cavities (e.g., first cavity 126a, second cavity 126b, third cavity 126c) in the second semiconductor wafer, as described herein.

As further shown in FIG. 11, process 1100 may include bonding the second semiconductor wafer to the first semiconductor wafer (block 1130). For example, one or more semiconductor processing tools may be used to bond the second semiconductor wafer to the first semiconductor wafer, as described herein. In some implementations, each MEMs structure of the plurality of MEMS structures is in a cavity of the plurality of cavities. In some implementations, a first cavity (e.g., first cavity 126a) of the plurality of cavities is surrounded by a first bonding structure (e.g., first bonding structure 124a) enclosing the first cavity. In some implementations, a second cavity (e.g., second cavity 126b or third cavity 126c) of the plurality of cavities is surrounded by a second bonding structure (e.g., second bonding structure 124b or third bonding structure 124c) enclosing the second cavity. In some implementations, a width (e.g., dimension D2 or dimension D3) of one or more portions of the second bonding structure in a direction (e.g., x-direction) along a bonding interface between the first semiconductor wafer and the second semiconductor wafer is smaller than a width (e.g., dimension D1) of the first bonding structure in the direction along the bonding interface.

Process 1100 may include additional implementations, such as any single implementation or any combination of implementations described below and/or in connection with one or more other processes described elsewhere herein.

In a first implementation, bonding the second semiconductor wafer to the first semiconductor wafer includes forming a eutectic bond between a germanium bonding layer (e.g., second bonding layer 122) of the second semiconductor wafer and a metal bonding layer (e.g., first bonding layer 120) of the first semiconductor wafer.

In a second implementation, alone or in combination with the first implementation, the plurality of MEMS structures each include a device configured to detect changes in cavity pressure based on energy lost from the device.

In a third implementation, alone or in combination with one or more of the first and second implementations, the one or more portions (e.g., recessed portions 206, 214, 218, 222, and/or recessed corner portion 210) of the second bonding structure include a recess in the second bonding structure.

In a fourth implementation, alone or in combination with one or more of the first through third implementations, a third cavity (e.g., third cavity 126c) of the plurality of cavities is surrounded by a third bonding structure (e.g., third bonding structure 124c) enclosing the third cavity, and a width (e.g., dimension D3) of one or more portions of the third bonding structure in the direction along a bonding interface between the first semiconductor wafer and the second semiconductor wafer is smaller than the width of the one or more portions of second bonding structure.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, product dies that include MEMS devices are manufactured on a wafer along with one or more process control monitoring (PCM) dies. The width of a seal structure around a cavity in the one or more PCM dies on the wafer is controlled so that the cavities of the PCM dies are more susceptible to gas leakage than the cavities of the product dies. The greater susceptibility to gas leakage allows for a greater amount of gas leakage into the cavity to be detected in the PCM dies during testing when process variations or defects occur on the wafer. In more detail, the width of the seal structure enables measurement of a change in the cavity pressure of a PCM die to be performed between a first time T₀ and a second time T₁. The change in cavity pressure may cause the quality factor (Q) of the PCM die to change by a greater amount than the product dies, thereby enabling leakage to be more easily detectable in the PCM dies without subjecting the product dies to damaging levels of stress. The seal structure may have different design variations for the shape of the seal structure, and for the locations at which the width is controlled. The quantity of PCM dies and product dies on a wafer can also vary.

As described in greater detail above, some implementations described herein provide a semiconductor structure. The semiconductor structure includes a first semiconductor die, where the first semiconductor die includes a first semiconductor device. The first semiconductor device includes a first cavity, a first micro-electromechanical-system (MEMS) structure in the first cavity, and a first seal structure around the first cavity and between a first semiconductor layer and a second semiconductor layer of the first semiconductor device. The semiconductor structure includes a second semiconductor die, where the second semiconductor die includes a second semiconductor device. The second semiconductor device includes a second cavity, a second MEMS structure in the second cavity, and a second seal structure around the second cavity and between a first semiconductor layer and a second semiconductor layer of the second semiconductor device, where a dimension of the first seal structure in a lateral direction with respect to the first cavity is greater than a dimension of the second seal structure in a lateral direction with respect to the second cavity.

As described in greater detail above, some implementations described herein provide a semiconductor structure. The semiconductor structure includes a device wafer. The semiconductor structure includes a capping wafer disposed over the device wafer in a first direction, where the capping wafer is bonded to the device wafer. The semiconductor structure includes a first micro-electromechanical-system (MEMS) structure in a first cavity formed by the capping wafer and the device wafer. The semiconductor structure includes a first bonding structure formed around the first cavity. The semiconductor structure includes a second MEMS structure in a second cavity formed by the capping wafer and the device wafer. The semiconductor structure includes a second bonding structure formed around the second cavity, where a dimension of the first bonding structure in a second direction is greater than a dimension of the second bonding structure in the second direction.

As described in greater detail above, some implementations described herein provide a method. The method includes forming a plurality of micro-electromechanical-system (MEMS) structures on a first semiconductor wafer. The method includes etching a second semiconductor wafer to form a plurality of cavities in the second semiconductor wafer. The method includes bonding the second semiconductor wafer to the first semiconductor wafer, where each MEMs structure of the plurality of MEMS structures is in a cavity of the plurality of cavities, where a first cavity of the plurality of cavities is surrounded by a first bonding structure enclosing the first cavity, where a second cavity of the plurality of cavities is surrounded by a second bonding structure enclosing the second cavity, and where a width of one or more portions of the second bonding structure in a direction along a bonding interface between the first semiconductor wafer and the second semiconductor wafer is smaller than a width of the first bonding structure in the direction along the bonding interface.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first semiconductor die,
wherein the first semiconductor die comprises a first semiconductor device comprising:
a first cavity;
a first micro-electromechanical-system (MEMS) structure in the first cavity; and
a first seal structure around the first cavity and between a first semiconductor layer and a second semiconductor layer of the first semiconductor device; and
a second semiconductor die,
wherein the second semiconductor die comprises a second semiconductor device comprising:
a second cavity;
a second MEMS structure in the second cavity; and
a second seal structure around the second cavity and between a first semiconductor layer and a second semiconductor layer of the second semiconductor device,
wherein a dimension of the first seal structure in a lateral direction with respect to the first cavity is greater than a dimension of the second seal structure in a lateral direction with respect to the second cavity.

2. The semiconductor structure of claim 1, wherein the dimension of the second seal structure comprises a substantially uniform width of the second seal structure around the second cavity.

3. The semiconductor structure of claim 1, wherein the dimension of the second seal structure comprises a reduced width at one or more first portions of the second seal structure in comparison to a width at one or more second portions of the second seal structure.

4. The semiconductor structure of claim 3, wherein the one or more first portions of the second seal structure comprise a recessed portion.

5. The semiconductor structure of claim 4, wherein the recessed portion faces the second cavity.

6. The semiconductor structure of claim 4, wherein the recessed portion faces away from the second cavity.

7. The semiconductor structure of claim 1, wherein a difference between the dimension of the second seal structure and the dimension of the first seal structure is included in a range of approximately 5% to approximately 10%.

8. The semiconductor structure of claim 1, further comprising a third semiconductor die,
wherein the third semiconductor die comprises a third semiconductor device comprising:
a third cavity;
a third MEMS structure in the third cavity; and
a third seal structure around the third cavity and between a first semiconductor layer and a second semiconductor layer of the third semiconductor device,
wherein the dimension of the second seal structure is greater than a dimension of the third seal structure in a lateral direction with respect to the third cavity.

9. The semiconductor structure of claim 1, wherein the first semiconductor die and the second semiconductor die are adjacent to each other.

10. The semiconductor structure of claim 1, wherein the first MEMS structure and the second MEMS structure each comprise a device configured to detect changes in cavity pressure based on a damping of the device.

11. A semiconductor structure, comprising:
a device wafer;
a capping wafer disposed over the device wafer in a first direction,
wherein the capping wafer is bonded to the device wafer;
a first micro-electromechanical-system (MEMS) structure in a first cavity formed by the capping wafer and the device wafer;
a first bonding structure formed around the first cavity;
a second MEMS structure in a second cavity formed by the capping wafer and the device wafer; and
a second bonding structure formed around the second cavity,
wherein a dimension of the first bonding structure in a second direction is greater than a dimension of the second bonding structure in the second direction.

12. The semiconductor structure of claim 11, wherein the first bonding structure and the second bonding structure each comprise a germanium layer and an aluminum layer.

13. The semiconductor structure of claim 11, wherein the first bonding structure forms a first seal around the first cavity, and
wherein the second bonding structure forms a second seal around the second cavity.

14. The semiconductor structure of claim 11, wherein the first cavity comprises one of a quadrilateral shape, a high-order polygon shape, a circular shape, or an oval shape, and
wherein the second cavity comprises one of the quadrilateral shape, the high-order polygon shape, the circular shape, or the oval shape.

15. The semiconductor structure of claim 11, wherein the second bonding structure comprises one of a symmetric distribution or an asymmetric distribution of a plurality of recessed portions in the second bonding structure.

16. A method, comprising:
forming a plurality of micro-electromechanical-system (MEMS) structures on a first semiconductor wafer;
etching a second semiconductor wafer to form a plurality of cavities in the second semiconductor wafer; and
bonding the second semiconductor wafer to the first semiconductor wafer,
wherein each MEMs structure of the plurality of MEMS structures is in a cavity of the plurality of cavities,
wherein a first cavity of the plurality of cavities is surrounded by a first bonding structure enclosing the first cavity,
wherein a second cavity of the plurality of cavities is surrounded by a second bonding structure enclosing the second cavity, and
wherein a width of one or more portions of the second bonding structure in a direction along a bonding interface between the first semiconductor wafer and the second semiconductor wafer is smaller than a width of the first bonding structure in the direction along the bonding interface.

17. The method of claim 16, wherein bonding the second semiconductor wafer to the first semiconductor wafer comprises:
forming a eutectic bond between a germanium bonding layer of the second semiconductor wafer and a metal bonding layer of the first semiconductor wafer.

18. The method of claim 16, wherein the plurality of MEMS structures each comprise a device configured to detect changes in cavity pressure based on energy lost from the device.

19. The method of claim 16, wherein the one or more portions of the second bonding structure comprise a recess in the second bonding structure.

20. The method of claim 16, wherein a third cavity of the plurality of cavities is surrounded by a third bonding structure enclosing the third cavity, and
wherein a width of one or more portions of the third bonding structure in the direction along a bonding interface between the first semiconductor wafer and the second semiconductor wafer is smaller than the width of the one or more portions of second bonding structure.
